(19) United States
(12) Patent Application Publication
(10) Pub. No.: US 2013/0279624 A1
(43) Pub. Date: Oct. 24, 2013

(54) High Performance Transmitter Having High Speed and Efficiency

(71) Applicant: BROADCOM CORPORATION, Irvine, CA (US)

(72) Inventors: Silvian Spiridon, Zeist (NL); Johan van der Tang, Zeist (NL); Han Yan, Rotterdam (NL); Hua-Feng Chen, Queen Creek, AZ (US)

(73) Assignee: BROADCOM CORPORATION, IRVINE, CA (US)

(21) Appl. No.: 13/625,183

(22) Filed: Sep. 24, 2012

Related U.S. Application Data
(60) Provisional application No. 61/637,177, filed on Apr. 23, 2012.

(51) Int. Cl. H03M 1/00; H04B 1/04

(52) U.S. Cl. 375/295

(57) ABSTRACT

According to an exemplary implementation, a transmitter includes a decoder circuit receiving a digital input from a digital back-end circuit. The decoder circuit includes a plurality of decoder cells. Each of the plurality of decoder cells is configured to drive a respective current source cell in a current source circuit so as to convert the digital input into an analog output. Each of the plurality of decoder cells has respective decoder logic. Furthermore, the digital input from the digital back-end circuit is respectively received by each of the plurality of decoder cells.

The present application claims the benefit of and priority to U.S. provisional application Ser. No. 61/637,177, filed on Apr. 23, 2012 and entitled “A 375 mW, 2.2 GHz Signal Bandwidth DAC-based Transmitter with an In-band IM3<−58 dBc in 40 nm CMOS.” The present application is also related to U.S. application Ser. No. 13/115,411, filed on May 25, 2011 and entitled “Single Stage and Scalable Serializer.” The above-identified applications are hereby fully incorporated by reference into the present application.

### BACKGROUND

Digital-to-analog converters (DACs) are used in a wide variety of applications and can have a critical impact on the accuracy and speed of data transfers. Thus, the DACs must often conform to strict performance requirements. Many applications for DACs, such as DAC-based transmitters, continue to demand higher speeds for both wired and wireless data transfer. The DACs for these applications should be capable of supporting high speeds. However, scaling up DAC speeds can introduce challenges in conforming to other performance requirements such as bit resolution, linearity, glitch energy, and monotonicity. Furthermore, in certain applications, such as those employing a system on chip (SoC), the DACs may also be subject to strict power and die area requirements.

### SUMMARY

The present disclosure is directed to a high performance transmitter having high speed and efficiency, substantially as shown in and/or described in connection with at least one of the figures, and as set forth more completely in the claims.

### BRIEF DESCRIPTION OF THE DRAWINGS

FIG. 1 illustrates a diagram of an exemplary transmitter.

FIG. 2 illustrates a diagram of a portion of an exemplary digital-to-analog converter (DAC).

FIG. 3 illustrates a diagram of a portion of an exemplary DAC.

### DETAILED DESCRIPTION

The following description contains specific information pertaining to implementations in the present disclosure. The drawings in the present application and their accompanying detailed description are directed to merely exemplary implementations. Unless noted otherwise, like or corresponding elements among the figures may be indicated by like or corresponding reference numerals. Moreover, the drawings and illustrations in the present application are generally not to scale, and are not intended to correspond to actual relative dimensions.

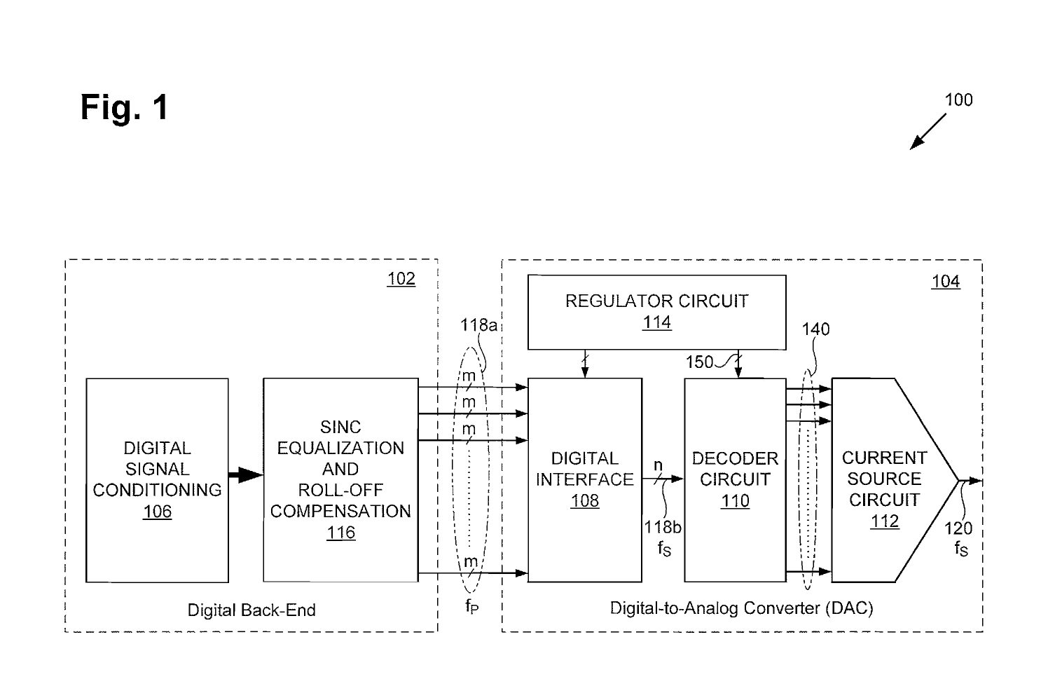

FIG. 1 illustrates a diagram of transmitter 100. Transmitter 100 includes digital back-end circuit 102 and digital-to-analog converter (DAC) 104. Digital back-end circuit 102 includes digital signal conditioning 106 and sinc equalization and roll-off compensation 116 (the term “sine” stands for the mathematical “sine function” as used in, for example, digital signal processing). DAC 104 includes digital interface 108, decoder circuit 110, current source circuit 112, and regulator circuit 114. In DAC 104, regulator circuit 114 is configured to power digital interface 108 and decoder circuit 110. For example, regulator circuit 114 powers decoder circuit 110 with supply voltages 150. In the present implementation, regulator circuit 114 includes a low-dropout regulator (LDO) circuit.

DAC 104 is coupled to digital back-end circuit 102. DAC 104 receives digital input 118a from digital back-end circuit 102 and generates analog output 120 from digital input 118a. As digital back-end circuit 102 is typically slow relative to other components in transmitter 100, in the implementation shown, digital input 118a is a parallel digital input. However in other implementations, digital input 118a is a serial digital input. Digital input 118a includes parallel m-bit channels, each configured to run at frequency f_{P}. Digital interface 108 of DAC 104 receives digital input 118a and provides digital input 118a to decoder circuit 110 from digital back-end circuit 102. In the present implementation, for example, digital interface 108 includes a serializer, which converts digital input 118a input serialized digital input 118b.

In the implementation shown, serialized digital input 118b includes an n-bit data stream configured to run at frequency f_{S}. In the present implementation, frequency f_{S} is equal to frequency f_{P} times the number of channels in digital input 118a. As one specific example, for illustrative purposes, digital input 118a can include eight channels and frequency f_{P} can be 625 MHz. Thus, frequency f_{S} of serialized digital input 118b would be 5 GHz in the present example.

Many serializers would cause a bottleneck in DAC 104 by being incapable of providing frequency f_{S} as frequency f_{P} times the number of channels in digital input 118a. However, one example of a suitable serializer design is disclosed in U.S. application Ser. No. 13/115,411, entitled “Single Stage and Scalable Serializer.” This serializer design can be utilized for each n-bit of serialized digital input 118b. To achieve frequency f_{S} of 5 GHz, shift clock CLK_{SH} in the above referenced disclosure would run at 5 GHz and load CLK_{L} in the above referenced disclosure would run at 625 MHz. Using this serializer design, digital interface 108 would not introduce a bottle neck into transmitter 100, while having low power consumption and small die area. For example digital interface 108 can consume 8 mW of power while occupying 0.0015 mm² of die area. It is noted that other serializer designs may be employed.

Decoder circuit 110 receives digital input 118a from digital back-end circuit 102. More particularly, in the present implementation, decoder circuit 110 receives digital input 118a from digital back-end circuit 102 through a serializer of digital interface 108 as serialized digital input 118b. Decoder circuit 110 drives current source circuit 112 so as to convert digital input 118a into analog output 120. More particularly, in the present implementation, decoder circuit 110 receives serialized digital input 118b and generates control signals 140 from serialized digital input 118b to drive circuit source circuit 112. In the present implementation, decoder circuit 110 is configured to utilize thermometric decoding for at least some of serialized digital input 118b. By utilizing thermometric decoding, transmitter 100 can achieve monotonicity with low glitch energy.

Current source circuit 112 receives control signals 140 from decoder circuit 110 and generates analog output 120 from control signals 140. As shown in FIG. 1, in the present implementation, frequency f_{S} can be sustained at analog output 120. Thus, DAC 104 of transmitter 100 is capable of supporting high speeds over wired or wireless data paths, which can be as high as 8 GHz or higher using current technologies. Transmitter 100 can support high speeds while meeting other performance requirements such as bit resolution, linearity, glitch energy, and monotonicity. Furthermore, in certain applications, transmitter 100 is on a system on chip (SoC) and can meet strict power and die area requirements.

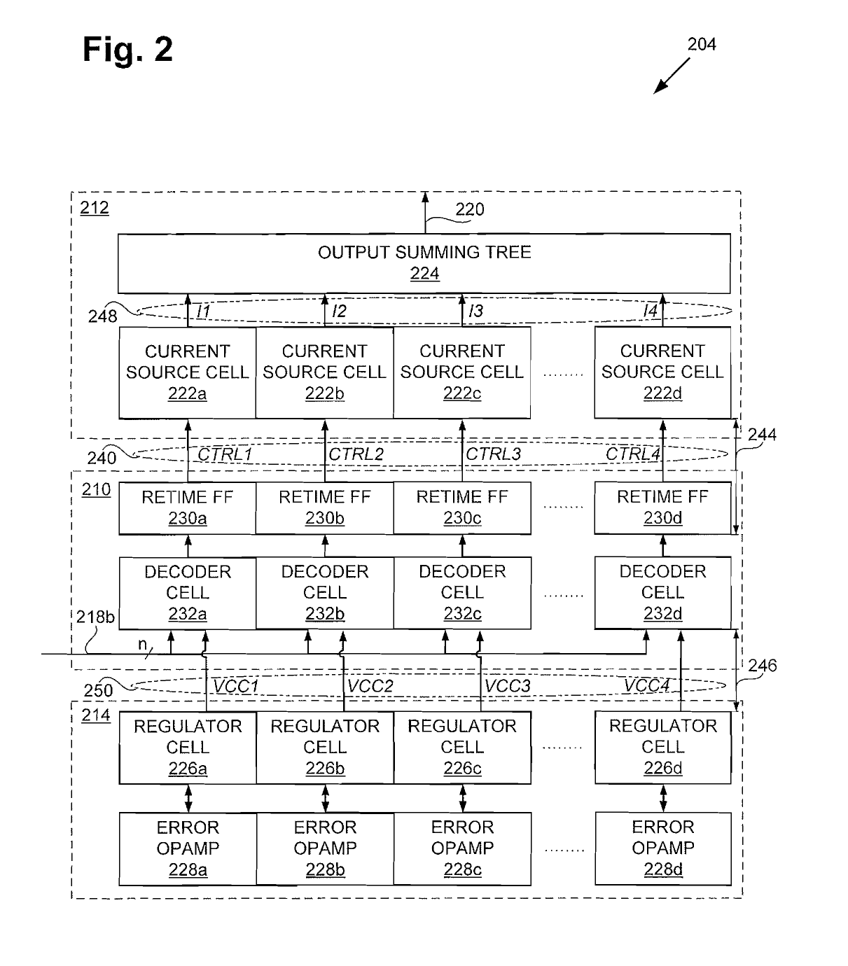

Referring now to FIG. 2, FIG. 2 illustrates a diagram of a portion of DAC 204, corresponding to DAC 104 in FIG. 1. In FIG. 2, DAC 204 includes decoder circuit 210, current source circuit 212, and regulator circuit 214, which correspond respectively to decoder circuit 110, current source circuit 112, and regulator circuit 114 in FIG. 1. Decoder circuit 210 includes decoder cells 232a, 232b, 232c, and 232d (also referred to collectively as “plurality of decoder cells 232” or “decoder cells 232”) and final retime flip-flops 230a, 230b, 230c, and 230d (also referred to collectively as “plurality of final retime flip-flops 230” or “final retime flip-flops 230”). Current source circuit 212 includes current source cells 222a, 222b, 222c, and 222d (also referred to collectively as “plurality of current source cells 222” or “current source cells 222) and output summing tree 224. Regulator circuit 214 includes regulator cells 226a, 226b, 226c, and 226d (also referred to collectively as “plurality of regulator cells 226” or “regulator cells 226”) and error opamps 228a, 228b, 228c, and 228d (also referred to collectively as “plurality of error opamps 228” or “error opamps 228”).

As shown in FIG. 2, decoder circuit 210 receives serialized digital input 218b, corresponding to serialized digital input 118b in FIG. 1. Digital input 118a, shown in FIG. 1, from digital back-end circuit 102, can be respectively received by each of decoder cells 232 as serialized digital input 218b. Thus, serialized digital input 218b may be referred to as a common digital input to decoder cells 232.

Decoder circuit 210 generates control signals 240, corresponding to control signals 140 in FIG. 1, from serialized digital input 218b to drive circuit source circuit 212. In FIG. 2, each of decoder cells 232 is configured to drive a respective current source cell 222 in current source circuit 212 so as to convert serialized digital input 118a, shown in FIG. 1, into analog output 220, corresponding to analog output 120 in FIG. 1. More particularly, each decoder cell 232 is configured to drive a respective current source cell 222 through a respective final retime flip-flop 230 using a respective control signal 240. Control signals 240 are provided to current source circuit 212 over respective control lines CTRL1, CTRL2, CTRL3, and CTRL4 (also referred to collectively as “control lines CTRL”). Current source cells 222 receive respective control signals 240 over control lines CTRL.

Thus, each decoder cell 232 is coupled to a respective current source cell 222. More particularly, each decoder cell 232 is coupled to a respective current source cell 222 through a respective final retime flip-flop 230. By using such a configuration, control lines CTRL can be of approximately a same length 244. Thus, each of decoder cells 232 can drive a respective current source cell 222 over approximately a same length 244. In other words, each of decoder cells 232 can provide a respective control signal 240 to a respective current source cell 222 over approximately a same length 244. In doing so, DAC 204 can avoid a speed bottleneck, which can be caused by delay introduced when at least one of control lines CTRL has a different length than others of control lines CTRL, thereby limiting maximum operating frequency of DAC 204.

DAC 204 achieves control lines CTRL of approximately a same length 244 by having a respective decoder cell 232 for each current source cell 222, as shown in FIG. 2. Thus, each respective decoder cells 232 can easily be placed a same distance away from a corresponding current source cell 222. Furthermore, each respective decoder cell 232 can be placed adjacent to the corresponding current source cell 222, allowing for length 244 to be relatively short. In doing so, DAC 204 can have low delay while also consuming low power as decoder cells 232 can drive current source cells 222 over short control lines CTRL.

As described above with respect to FIG. 1, decoder circuit 210 can be configured to utilize thermometric decoding for at least some of serialized digital input 218b. By utilizing thermometric decoding, DAC 204 can achieve monotonicity with low glitch energy. However, thermometric decoding introduces additional control signals 240 to be routed to a respective current source cell 222. As one example, serialized digital input 218b can be an n-bit data stream where n is nine. In this example, decoder circuit 210 utilizes thermometric decoding for the first six most significant bits (MSBs) of serialized digital input 218b, but not for the remaining three least significant bits (LSBs). Thus, decoder circuit 210 has 66 current source cells receiving 66 control signals 240 to be routed (i.e. 63 for the MSBs and 3 for the LSBs). Advantageously, routing of control signals 240 is made simple in DAC 204 due to each respective decoder cell 232 corresponding to a respective current source cell 222. Thus, control signals 240 can easily be scaled without jeopardizing maximum operating frequency and other performance requirements of DAC 204.

Current source cells 222 generate output currents 248 respectively from control signals 240. Current source cells 222 provide output currents 248 to output summing tree 224 over respective current lines I1, I2, I3, and I4. Output summing tree 224 receives output currents 248 from current source cells 222 and sums output currents 248 to generate analog output 220.

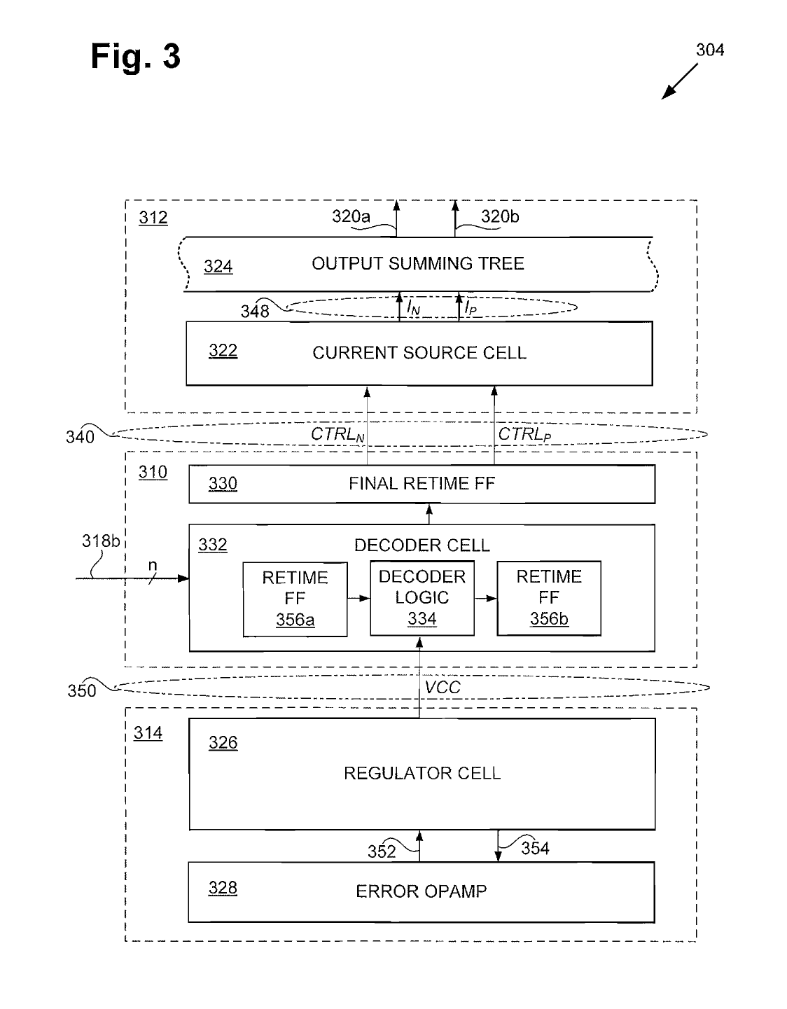

Implementations of DAC 204 are described in additional detail below with respect to FIG. 3. Referring to FIG. 3, FIG. 3 illustrates a portion of DAC 304, corresponding to DAC 204 in FIG. 2. DAC 304 includes decoder circuit 310, current source circuit 312, and regulator circuit 314, which correspond respectively to decoder circuit 210, current source circuit 212, and regulator circuit 214 in FIG. 2.

In FIG. 3, decoder circuit 310 includes decoder cell 332, which includes decoder logic 334 situated between retime flip-flops 356a and 356b. Decoder cell 332 corresponds to any of decoder cells 232 in FIG. 2. Thus, in FIG. 2, each of decoder cells 232 can have respective decoder logic 334 (at least some of respective decoder logic 334 may perform different decoding algorithms). Similarly, in FIG. 2, each of decoder cells 232 can have respective retime flip-flops 356a and 356b, which can be utilized to synchronize input to and output from each respective decoder logic 334 amongst decoder cells 232. Decoder logic 334 is configured to provide control signal 340 to current source cell 322 so as to convert serialized digital input 318b into negative analog output 320a and positive analog output 320b (also referred to collectively as “differential analog output 320”).

Serialized digital input 318b corresponds to serialized digital input 218b in FIG. 2. Differential analog output 320 corresponds to a differential implementation of analog output 220 in FIG. 2. Furthermore, current source cell 322 corresponds to any of current source cells 222 in FIG. 2. Thus, in FIG. 2, each respective decoder logic 334 can be configured to provide a respective control signal 240 to a respective current source cell 222 so as to convert serialized digital input 218a into analog output 220. Each respective decoder logic 334 of decoder cells 232 also can provide the respective control signal 240 to the respective current source cell 222 over approximately a same length.

As described above, differential analog output 320 in FIG. 3 corresponds to a differential implementation of analog output 220 in FIG. 2. In the implementation shown, DAC 304 includes final retime flip-flop 330, which can correspond to any of final retime flip-flops 230 in FIG. 2. Final retime flip-flop 330 is utilized to convert output from decoder cell 332 into a differential signal as differential control signal 340 and may include two cascaded latches. Differential control signal 340 can be provided to current source cell 322 over negative control line CTRL_{N} and positive control line CTRL_{P}. Thus, in FIG. 2, each respective control signal 240 can be provided to each respective current source cell 222 as a differential signal.

Current source cell 322 can generate differential current 348 from differential control signal 340 and provide differential current 348 to output summing tree 324 over negative current line I_{N} and positive current line I_{P}. Output summing tree 324 can generate negative analog output 320a from negative current line I_{N} and positive analog output 320b from positive current line I_{P}.

In FIG. 2, regulator circuit 214 powers each of decoder cells 232 in DAC 204. This may be accomplished, for example, utilizing an LDO regulator that generates a supply voltage, which is then provided to decoder cells 232. However, in the implementation shown, DAC 204 includes regulator circuit 214 respectively powering each decoder cells 232 in DAC 204 with supply voltages 250, corresponding to supply voltages 150 in FIG. 1. Supply voltages 250 are provided to decoder circuit 210 over power respective lines VCC1, VCC2, VCC3, and VCC4 (also referred to herein collectively as “power lines VCC”). As shown in FIG. 2, a respective regulator cell 226 is powering a respective decoder cell 232 for each of decoder cells 232 over a respective power line VCC. By using such a configuration, power lines VCC can be of approximately a same length 246. In other words, each of regulator cells 226 can power respective decoder cell 232 over approximately a same length 246.

In the present implementation, regulator cells 226 are configured to each output a same supply voltage 250. The voltage received by each decoder cell 232 is proportional to delay introduced by length 246. Thus, because each of regulator cells 226 can power a respective decoder cell 232 over approximately a same length 246, the voltage received by each decoder cell 232 can easily be made the same. DAC 204 can thereby avoid, for example, different switch timings in decoder cells 232, which could introduce distortion. Furthermore, DAC 204 can easily be scaled to accommodate additional power lines VCC.

Also in the present implementation, a respective error opamp 228 is coupled to each respective regulator cell 226. The respective error opamp 228 can adjust a supply voltage 250 from the respective regulator cell 226. This relationship is shown in additional detail with respect to FIG. 3. In FIG. 3, regulator cell 326 can correspond to any of regulator cells 226 in FIG. 2. Furthermore, error opamp 328 can correspond to any of error opamps 228 in FIG. 2. Error opamp 328 receives feedback 354 from regulator cell 326. In the present implementation, regulator cell 326 is an LDO cell, however other types of regulator cells can be utilized. Feedback 354 can be from a pass transistor of regulator cell 326 and may be equal to supply voltage 350. The pass transistor provides the supply voltage 350 to the decoder cell 332. Error opamp 328 can generate control voltage 352 based on feedback 354 to adjust supply voltage 350. For example, control voltage 352 may be provided to a gate of the pass transistor of regulator cell 326. Utilizing such a configuration, DAC 204 can provide stable supply voltages 250 to decoder circuit 210. Furthermore, regulator cells 226 have a different supply than error opamps 228 to increase power efficiency.

Thus, as discussed above, in the embodiments of FIGS. 1 through 3, various implementations of the present disclosure can provide for a transmitter that is capable of supporting high speeds. Additionally, the transmitter can achieve high speeds while meeting performance objectives with respect to bit resolution, linearity, glitch energy, and monotonicity along with power and die area efficiency requirements.

From the above description it is manifest that various techniques can be used for implementing the concepts described in the present application without departing from the scope of those concepts. Moreover, while the concepts have been described with specific reference to certain implementations, a person of ordinary skill in the art would recognize that changes can be made in form and detail without departing from the scope of those concepts. As such, the described implementations are to be considered in all respects as illustrative and not restrictive. It should also be understood that the present application is not limited to the particular implementations described above, but many rearrangements, modifications, and substitutions are possible without departing from the scope of the present disclosure.

1. A transmitter comprising:
a decoder circuit receiving a digital input from a digital back-end circuit;
said decoder circuit comprising a plurality of decoder cells;
each of said plurality of decoder cells configured to drive a respective current source cell in a current source circuit so as to convert said digital input into an analog output.

2. The transmitter of claim 1, wherein each of said plurality of decoder cells has a respective decoder logic.

3. The transmitter of claim 1, wherein said digital input from said digital back-end circuit is respectively received by each of said plurality of decoder cells.

4. The transmitter of claim 1, wherein each of said plurality of decoder cells is configured to provide a respective control signal to said respective current source cell so as to convert said digital input into said analog output.

5. The transmitter of claim 1 comprising a respective regulator cell powering a respective decoder cell of said plurality of decoder cells.

6. The transmitter of claim 1 comprising a respective error opamp coupled to said respective regulator cell.

7. The transmitter of claim 1, wherein said decoder circuit is configured to utilize thermometric decoding.

8. The transmitter of claim 1, wherein each of said plurality of decoder cells is configured to drive said respective current source cell through a respective retime flip-flop.

9. A transmitter comprising:
a plurality of decoder cells receiving a common digital input;
said plurality of decoder cells each coupled to a respective current source cell of a plurality of current source cells;
said plurality of decoder cells having respective decoder logic, said respective decoder logic configured to provide a respective control signal to said respective current source cell so as to convert said common digital input into an analog output.

10. The transmitter of claim 9, wherein said respective decoder logic is configured to provide said respective control signal to said respective current source cell over a respective control line.

11. The transmitter of claim 9 comprising a respective regulator cell powering a respective decoder cell of said plurality of decoder cells.

12. The transmitter of claim 9, wherein said respective decoder logic is situated between respective retime flip-flops.

13. The transmitter of claim 9, wherein said respective control signal is provided to said respective current source cell as a differential signal.

14. A transmitter comprising:
a digital-to-analog converter (DAC) coupled to a digital back-end circuit;
said DAC comprising a digital interface, a decoder circuit, and a current source circuit;
said digital interface providing a digital input to said decoder circuit from said digital back-end circuit;
said decoder circuit driving said current source circuit so as to convert said digital input into an analog output;
said decoder circuit comprising a plurality of decoder cells, each of said plurality of decoder cells configured to drive a respective current source cell in said current source circuit.

15. The transmitter of claim 14, wherein said DAC comprises a regulator circuit respectively powering each of said plurality of decoder cells in said DAC.

16. The transmitter of claim 14 comprising a respective regulator cell powering a respective decoder cell of said plurality of decoder cells.

17. The transmitter of claim 14, wherein each of said plurality of decoder cells is configured to provide a respective control signal to said respective current source cell so as to convert said digital input into said analog output.

18. The transmitter of claim 15 comprising a respective error opamp coupled to a respective regulator cell in said regulator circuit.

19. The transmitter of claim 14, wherein said decoder circuit is configured to utilize thermometric decoding.

20. The transmitter of claim 14, wherein each of said plurality of decoder cells is configured to drive said respective current source cell through a respective retime flip-flop.
